(19) United States
(12) Patent Application Publication
(10) Pub. No.: US 2011/0120751 A1
(43) Pub. Date: May 26, 2011

(54) ACCURATE IMPEDANCE DESIGNING METHOD FOR CIRCUIT LAYOUT

(75) Inventors: Po-Yuan Shih, Taipei (TW); Chien-Cheng Chen, Taipei (TW)

(73) Assignee: INVENTEC CORPORATION, Taipei (TW)

(21) Appl. No.: 12/827,967

(22) Filed: Jun. 30, 2010

(30) Foreign Application Priority Data
Nov. 20, 2009 (TW) 098139636

(51) Int. Cl. H05K 1/02

(52) U.S. Cl. 174/250

(57) ABSTRACT

The present invention relates to an accurate impedance designing method for a circuit layout. On a printed circuit board, opening circuit for a soldering pad of a electric device and a signal wire of the device so as to form a non-electrical connection between the soldering pad and the signal wire, thus, the impedance of the soldering pad is not involved at a detecting point so as to enhance the accuracy of the current signal measuring.

### FIELD OF THE INVENTION

The present invention relates to an accurate impedance designing method for a circuit layout, and more particularly, to a circuit layout with accurate impedance design adapted for a printed circuit board (PCB), capable of enhancing the accuracy of the current signal measuring of an electric device on the PCB by enabling a non-electrical connection to be formed between soldering pads of the electric device and a signal wire of the same electric device so as to deter the impedance of the soldering pads from involving at a detecting point while the pins of the electric device are electrically connected with the soldering pad and the signal wire simultaneously.

### BACKGROUND OF THE INVENTION

With rapid advance of electronic industry, the design and manufacture of electronic products are becoming more and more sophisticated. Accordingly, it is critical to have a good PCB layout design capable of accommodating all the electric devices required for such sophisticated electronic products in the limited space available on a PCB while still connecting all the signal lines accurately and precisely for allowing the same to function properly. Moreover, the PCB layout should enables all the characteristics, such as driving voltage, current value and impedance value, of each and every electric device engaged thereat to be measured accurately so as to product an electronic product with good reliability.

For certain power ICs, it is required to measure and obtain a current value of a signal line for the corresponding power control operations governed by the power ICs. Please refer to FIG. 1, which is a schematic diagram showing the use of a power IC for detection current between two impedance nodes A and B. In FIG. 1, by detecting the resistance between the two impedance nodes A and B, the power IC 1 is able to calculate a current value to be used as a control parameter of the power IC 1 relating to the providing of sufficient current to a specific electric device for supporting the same to operate normally. Nevertheless, for enabling the circuit layer to support signals of larger current, not only the signal lines 3 connecting the power IC 1 to the two impedance nodes A and B should be formed with large-area copper foil, but also the two copper soldering pads 2 being provided at the two impedance nodes A and B should be formed with copper foils of specific area, as shown in FIG. 2. Accordingly, the power IC 1 is able to detect the voltage difference between the two impedance nodes A and B through the two signal lines 3, and thereby, a current value can be calculated and obtained with reference to the resistance existed between the two impedance nodes A and B. However, it is noted that the positioning of the signal lines 3 are going to introduce errors to the voltage difference measured between the two nodes A and B as the impedances of the two soldering pads 2 will also be counted into the resistance existed between the two impedance nodes A and B. In an embodiment for performing a detection between the two nodes A and B as shown in FIG. 3, it is assume that the impedance between the impedance nodes A and B is 10Ω and the predefined measurement voltage is 10V, therefore, a current of 1 A can be obtained according to the formula: V=I×R. However, since there are copper foils existed in the layout whose impedance is 2Ω, the detection is actually performed between the node A and the node C with an actual impedance of 10Ω+2Ω=12Ω, and thus the actual voltage will be 12V. Nevertheless, the power IC will still use the predefined measurement voltage is 10V in the formula: V=I×R for calculating the current value, and thus an erroneous current of 1.2 A is obtained according to 12=I×10, which is differed from the predefined current of 1 A by 0.2 A. Accordingly, the aforesaid circuit layout is going to cause mistake in the calculation relating to the providing of current to an electric device, so that it is very often going to cause an electronic product to malfunction. Therefore, it is in need of a method for overcoming the aforesaid problem.

### SUMMARY OF THE INVENTION

In view of the disadvantages of prior art, the primary object of the present invention is to provide an accurate impedance designing method for constructing a circuit layout with accurate impedance design adapted for a printed circuit board (PCB), capable of enhancing the accuracy of the current signal measuring of an electric device on the PCB by enabling a non-electrical connection to be formed between soldering pads of the electric device and a signal wire of the same electric device so as to deter the impedance of the soldering pads from involving at a detecting point while the pins of the electric device are electrically connected with the soldering pad and the signal wire simultaneously.

Another object of the invention is to provide a modularized layout design, which separates soldering pads of an electric device on a PCB from its corresponding signal lines for not only enabling different signal lines to be arranged respectively according to the types of signal being transferred so as to accurately calculate the length and width of the signal lines, but also deterring the impedance of the soldering pads from involving at the detection. As the circuit layout is modularized, the circuit characteristic will not be affected just because it is designed by a senior layout designer or by a junior layout designer. Moreover, it is noted that the separation of the soldering pads from the signal lines is not cause any change to the PCB production line and also is not going to cause any increase in production cost.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a schematic diagram showing the conventional use of a power IC for detection current between two impedance nodes A and B.

FIG. 2 is a schematic diagram showing the serial connection of larger-area soldering pads and signal lines according to prior arts.

FIG. 3 is a schematic diagram showing an equivalent impedance between the node A and node B for the detection of a power IC resulting from the serial connecting of a soldering pad.

FIG. 4 a schematic diagram showing the separation of soldering pads and signal lines of an electric device according to the present invention.

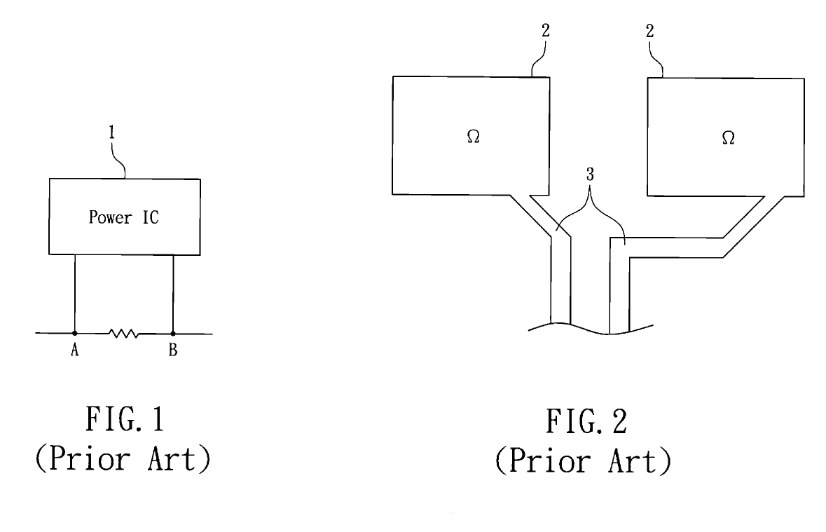

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

Please refer to FIG. 4 a schematic diagram showing the separation of soldering pads and signal lines of an electric device according to the present invention. As illustrated in FIG. 4, the accurate impedance designing method of the invention is characterized in that: a non-electrical connection is formed between soldering pads of an electric device on a printed circuit board (PCB) and signal wires of the same electric device so as to deter the impedance of the soldering pads from involving at a detecting point while the pins of the electric device are electrically connected with the soldering pad and the signal wire simultaneously, and thus enhancing the accuracy of the current signal measuring of the electric device on the PCB.

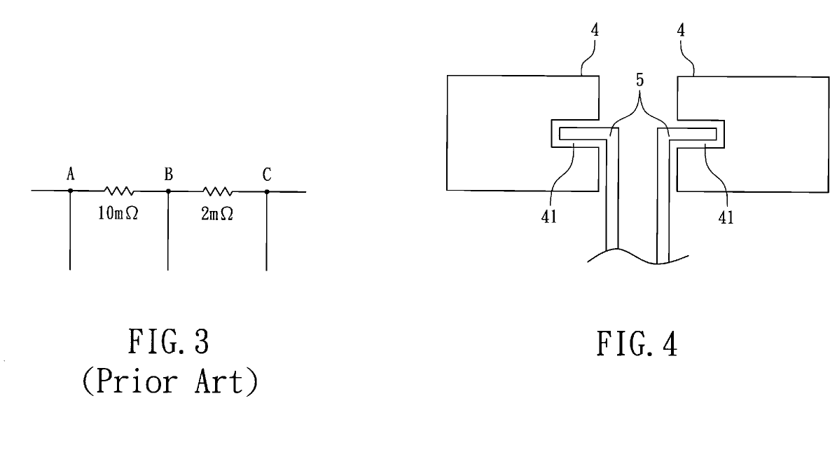

As the aforesaid soldering pads and signal lines are all made of a copper foil that is separated so as to form the independent soldering pads 4 and signal lines 5, as shown in FIG. 4. However, on the PCB, the electric device corresponding to the soldering pads 4 and signal lines 5 is connected electrically to the soldering pads 4 and signal lines 5 by the pins thereof simultaneously. It is noted that the soldering pads 4 and the signal lines are provided to transfer different signals that they can be treated as two different signal lines in view of circuit layout. In the present invention, the circuit layout of the PCB will not be affected by the separation of the soldering pads 4 and signal lines 5, only will enable to the impedance of the soldering pads 4 to be deterred from involving at a detecting point without changing the positioning of the independent signal lines 5. In the embodiment shown in FIG. 3 whereas the impedance between the impedance nodes A and B is 10Ω is the only impedance being involved at the detecting point and the predefined measurement voltage is 10V, a current of 1 A can be obtained according to the formula: V=I×R. It is noted that the impedances of the soldering pads 4 will not be involved at the detection so that the accuracy of current measurement is enhanced. Moreover, each soldering pad 4 is formed with a recess 41 for receiving an end of its corresponding signal line 5. It is noted that by the designing of the recess 41, the area required for the layout of the soldering pads 4 and signal lines 5 is reduced. In addition, each signal line 5 is arranged extending from the recess 41 and then cornered vertically at least once so as to form a signal line layout, or each signal line 5 is arranged extending from the recess 41 on a layer of the PCB and then passing through a through hole to another layer of the PCB so as to form a signal line layout.

As shown in FIG. 4, the present invention provides a modularized layout design, which separates soldering pads of an electric device on a PCB from its corresponding signal lines for not only enabling different signal lines to be arranged respectively according to the types of signal being transferred so as to accurately calculate the length and width of the signal lines, but also deterring the impedance of the soldering pads from involving at the detection. As the circuit layout is modularized, the circuit characteristic will not be affected just because it is designed by a senior layout designer or by a junior layout designer. Moreover, it is noted that the separation of the soldering pads from the signal lines is not cause any change to the PCB production line and also is not going to cause any increase in production cost.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. An accurate impedance designing method, characterized in that: a non-electrical connection is formed between soldering pads of an electric device on a printed circuit board (PCB) and signal wires of the same electric device so as to deter the impedance of the soldering pads from involving at a detecting point while the pins of the electric device are electrically connected with the soldering pad and the signal wire simultaneously, and thus enhancing the accuracy of the current signal measuring of the electric device on the PCB.

2. The method of claim 1, wherein each soldering pad is formed with a recess for receiving an end of its corresponding signal line.

3. The method of claim 1, wherein signals from the detecting point is sent to a power IC to be used for calculating a current value.

4. The method of claim 2, wherein each signal line is arranged extending from the corresponding recess and then cornered vertically at least once so as to form a signal line layout.

5. The method of claim 2, wherein each signal line is arranged extending from the recess on a layer of the PCB and then passing through a through hole to another layer of the PCB so as to form a signal line layout.

6. An accurate impedance designing method, characterized in that: a non-electrical connection is formed between soldering pads of an electric device on a printed circuit board (PCB) and signal wires of the same electric device so as to deter the impedance of the soldering pads from involving at a detecting point while the pins of the electric device are electrically connected with the soldering pad and the signal wire simultaneously, and thus enhancing the accuracy of the current signal measuring of the electric device on the PCB; and accordingly, each soldering pad is formed with a recess for receiving an end of its corresponding signal line while enabling signal line to be arranged extending from the corresponding recess and then cornered vertically at least once on a layer of the PCB and then passing through a through hole to another layer of the PCB so as to form a signal line layout; and thereby, signals from the detecting point is sent to a power IC to be used for calculating a current value.
